(19) United States
(12) Patent Application Publication
(10) Pub. No.: US 2016/0316578 A1
(43) Pub. Date: Oct. 27, 2016

(54) DISPLAY DEVICE FRAME AND MULTI-DISPLAY DEVICE HAVING THE SAME

(71) Applicant: Samsung Display Co., Ltd., Yongin-si (KR)

(72) Inventor: Jiwon CHA, Asan-si (KR)

(21) Appl. No.: 14/927,576

(22) Filed: Oct. 30, 2015

(30) Foreign Application Priority Data
Apr. 21, 2015 (KR) 10-2015-0056178

(51) Int. Cl. H05K 5/00; G02B 5/08; H05K 5/04

(52) U.S. Cl. CPC H05K 5/0021; H05K 5/0017; H05K 5/04; G02B 5/08

(57) ABSTRACT

A multi-display device includes: a plurality of display panels adjacent to each other; and a first upper frame between the display panels adjacent to each other. The first upper frame may include: a partition wall portion between the display panels adjacent to teach other; and a bezel portion extended from the partition wall portion to overlap front surface edges of each of the display panels adjacent to each other.

This application claims priority to Korean Patent Application No. 10-2015-0056178, filed on Apr. 21, 2015, and all the benefits accruing therefrom under 35 U.S.C. §119, the disclosure of which is incorporated herein in its entirety by reference.

### BACKGROUND

1. Field

Exemplary embodiments of the invention relate to a multi-display device capable of efficiently reducing visibility of a non-display area between adjacent display devices among display devices constituting the multi-display device.

2. Description of the Related Art

Display devices are classified into various types including liquid crystal display (“LCD”) devices, organic light emitting diode (“OLED”) display devices, plasma display panel (“PDP”) devices, electrophoretic display (“EPD”) devices, and the like, based on a light emitting method thereof

Multi-display devices in which a plurality of separate or individual display devices are combined with each other such as in a tiling manner to realize a single large screen are in use so as to provide various types of information and advertisement in a relatively large format.

As for the multi-display device, reducing visibility of a non-display area between adjacent display devices among display devices constituting the multi-display device is critical so that an uninterrupted or unbroken overall single screen of the multi-display device may be perceived.

### SUMMARY

Exemplary embodiments of the invention are directed to a multi-display device for which visibility of a non-display area between adjacent display devices among display devices constituting the multi-display device is reduced or effectively prevented.

According to an exemplary embodiment of the invention, a multi-display device includes: a plurality of display panels adjacent to each other; and a first upper frame between the display panels adjacent to each other. The first upper frame includes: a partition wall portion between the display panels adjacent to each other; and a bezel portion extended from the partition wall portion to overlap front surface edges of the display panels adjacent to each other.

The plurality of display panels may each include a display area in which an image is displayed, and a non-display area around the display area and in which the image is not displayed. The bezel portion may be disposed in the non-display area of each of the display panels adjacent to each other.

The multi-display device may further include a second upper frame, the second upper frame including: an outer edge bezel portion in the non-display area at an outer edge of the multi-display device; and a lateral wall portion extended from the outer edge bezel portion along an outer side surface of the multi-display device.

The first upper frame and the second upper frame may each include at least one of stainless steel, aluminum, aluminum alloys, magnesium, magnesium alloys, copper, copper alloys and an electro-galvanized steel sheet.

The multi-display device may further include an adhesive between the first upper frame and the display panels adjacent to each other and between the second upper frame and the display panels adjacent to each other.

The first upper frame may further include an optical structure on the bezel portion.

The optical structure may have one of a triangular, quadrangular and circular cross-section.

The optical structure may include at least one of polycarbonate (“PC”), polymethyl methacrylate (“PMMA”), an acrylonitrile-butadiene-styrene (“ABS”) copolymer and an acrylic resin.

The first upper frame may further include a reflection member, and the reflection member may be on an outer surface of the optical structure.

The reflection member may include at least one of gold (Au), silver (Ag), copper (Cu), aluminum (Al), chromium (Cr), titanium (Ti) and a metal alloy thereof

The multi-display device may further include an adhesive between the bezel portion and the optical structure to fix the bezel portion to the optical structure.

According to another exemplary embodiment of the invention, a multi-display device includes: a plurality of display panels adjacent to each other; and a first upper frame between the display panels adjacent to each other. The first upper frame may include: an optical structure which extends to overlap front surface edges of the display panels adjacent to each other; and a partition wall portion between the display panels adjacent to each other, the partition wall portion extended into the optical structure which extends to overlap the front surface edges of the display panels adjacent to each other.

The plurality of display panels may each include a display area in which an image is displayed, and a non-display area around the display area and in which the image is not displayed. The optical structure may be disposed in the non-display area of each of the display panels adjacent to each other.

The multi-display device may further include a second upper frame, the second upper frame including: an outer edge bezel portion in the non-display area at an outer edge of the multi-display device; and a lateral wall portion extended downwards from the outer edge bezel portion along an outer side surface of the multi-display device.

The partition wall portion and the second upper frame may each include at least one of stainless steel, aluminum, aluminum alloys, magnesium, magnesium alloys, copper, copper alloys and an electro-galvanized steel sheet.

The optical structure may include at least one of polycarbonate (“PC”), polymethyl methacrylate (“PMMA”), an acrylonitrile-butadiene-styrene copolymer (“ABS”) and an acrylic resin.

The multi-display device may further include an adhesive between the optical structure and the display panels adjacent to each other, the adhesive fixing the optical structure to the adjacent display panels of which the front surface edges thereof area overlapped by the optical structure.

The optical structure may have one of a triangular, quadrangular, and circular cross-section.

The first upper frame may further include a reflection member, and the reflection member may be on an outer surface of of the optical structure.

The reflection member may include at least one of gold (Au), silver (Ag), copper (Cu), aluminum (Al), chromium (Cr), titanium (Ti) and a metal alloy thereof

According to one or more exemplary embodiment of the invention, a multi-display device has a structure in which a plurality of display panels disposed adjacent to each other share a single frame, and thereby an overall width of a non-display area of the multi-display device may be reduced by a thickness of a portion of the frame.

Further, according to one or more exemplary embodiment of the invention, a multi-display device may include an optical structure disposed at an inner non-display area between a plurality of display devices adjacent to each other, and thereby visibility of the inner non-display area may be efficiently reduced.

### BRIEF DESCRIPTION OF THE DRAWINGS

The above and other features of the invention will be more clearly understood from the following detailed description taken in conjunction with the accompanying drawings, in which:

FIG. 1 is a perspective view illustrating an exemplary embodiment of a multi-display device according to the invention;

FIG. 2 is an exploded perspective view illustrating the multi-display device of FIG. 1;

FIG. 3 is a perspective view illustrating an exemplary embodiment of an upper frame of a multi-display device according to the invention;

FIG. 4 is a cross-sectional view taken along line I-I of FIG. 1;

FIGS. 5, 6 and 7 are cross-sectional views illustrating other exemplary embodiments of a multi-display device according to the invention.

### DETAILED DESCRIPTION

Hereinafter, exemplary embodiments of the invention will be described in more detail with reference to the accompanying drawings.

Although the invention can be modified in various manners and have several exemplary embodiments, specific exemplary embodiments are illustrated in the accompanying drawings and will be mainly described in the specification. However, the scope of the invention is not limited to the specific exemplary embodiments and should be construed as including all the changes, equivalents, and substitutions included in the spirit and scope of the invention.

Throughout the specification, when an element is referred to as being “connected” to another element, the element is “physically connected” to the other element or “electrically connected” to the other element with one or more intervening elements interposed therebetween. When an element is referred to as being “directly connected” to another element, the element is “physically connected” to the other element or “electrically connected” to the other element with no intervening elements interposed therebetween.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof

It will be understood that, although the terms “first,” “second,” “third,” and the like may be used herein to describe various elements, these elements should not be limited by these terms. These terms are only used to distinguish one element from another element. Thus, “a first element” discussed below could be termed “a second element” or “a third element,” and “a second element” and “a third element” can be termed likewise without departing from the teachings herein.

Some of the parts which are not associated with the description may not be provided in order to specifically describe exemplary embodiments of the invention, and like reference numerals refer to like elements throughout the specification.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, an exemplary embodiment of display device according to the invention will be described with respect to a liquid crystal display (“LCD”) device. However, features of the invention may be applicable to other display devices such as an organic light emitting diode (“OLED”) display device or a plasma display panel (“PDP”) device as well as the LCD device.

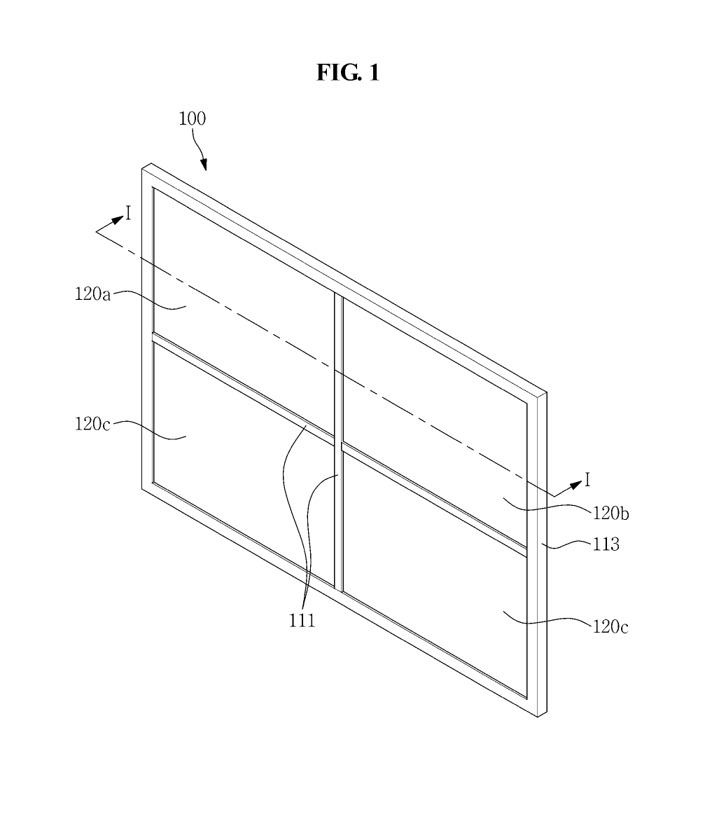

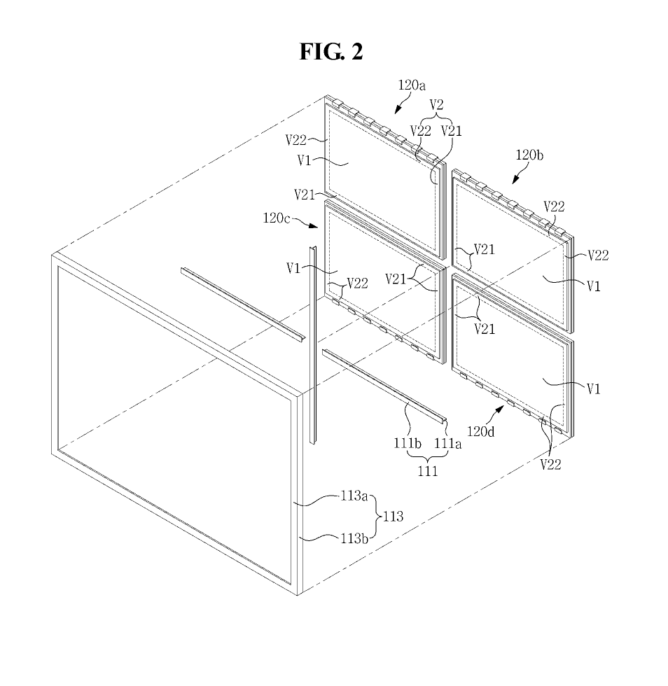

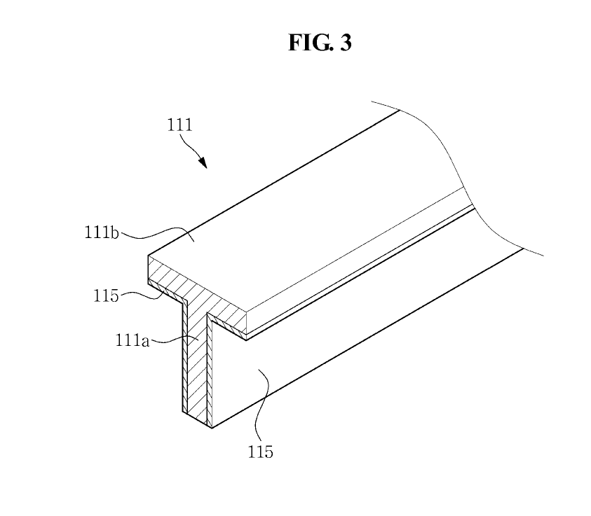

FIG. 1 is a perspective view illustrating an exemplary embodiment of a multi-display device 100 according to the invention. FIG. 2 is an exploded perspective view illustrating the multi-display device 100 of FIG. 1. FIG. 3 is a perspective view illustrating an exemplary embodiment of an upper frame of a multi-display device according to the invention.

In reference to FIGS. 1, 2 and 3, the multi-display device 100 includes a plurality of display panels 120a, 120b, 120c and 120d arranged in a matrix form and various frame members for accommodating and supporting the display panels 120a, 120b, 120c and 120d.

The plurality of display panels 120a, 120b, 120c and 120d may each display a divided image as a portion of an overall image to be displayed on the multi-display device 100. The multi-display device 100 may combine the divided images to display a single overall large image.

The exemplary embodiment of the multi-display device 100 is described as including four display panels 120a, 120b, 120c and 120d arranged in two rows disposed at upper and lower portions of a single overall screen of the multi-display device 100 and two columns at left and right portions of the single overall screen (i.e., 2×2 arrangement), but the invention is not limited thereto. Exemplary embodiments, of the multi-display device 100 according to the invention may include any of a number of display panels such as a plurality of display panels having a 3×3 or 4×4 arrangement to provide a larger overall screen than provided by the 2×2 arrangement.

The display panels 120a, 120b, 120c and 120d may each include a display area V1 on which an image is displayed and a non-display area V2 around the display area V1. The non-display area V2 may include a first non-display area V21 between the respective display panels 120a, 120b, 120c and 120d and a second non-display area V22 at an outer edge of the multi-display device 100. The first and second non-display areas V21 and V22 of individual display panels may define a portion of the non-display area of the multi-display device 100, such as when the individual display panels are assembled together with frame members to be described below.

Upper frames 111 and 113 may be disposed in the non-display area V2 of the respective display panels 120a, 120b, 120c and 120d. The upper frames 111 and 113 may include at least one of stainless steel, aluminum, aluminum alloys, magnesium, magnesium alloys, copper, copper alloys and an electro-galvanized steel sheet, but the invention is not limited thereto.

The upper frames 111 and 113 may include a first upper frame 111 disposed in the first non-display area V21 and a second upper frame 113 disposed in the second non-display area V22.

The first upper frame 111 may include a partition wall portion 111a disposed between adjacent display panels among the display panels 120a, 120b, 120c and 120d.

The first upper frame 111 may further include a bezel portion 111b laterally bent from the partition wall portion 111a to extend therefrom. The bezel portion 111b is disposed in the first non-display area V21 of adjacent display panels among the display panels 120a, 120b, 120c and 120d. The first upper frame 111 may define the partition wall portion 111a thereof and the bezel portion 111b thereof.

The partition wall portion 111a may be disposed between adjacent display panels among the respective display panels 120a, 120b, 120c and 120d of the multi-display device 100. Referring to FIG. 3, a length of the partition wall portion 111a extends from the bezel portion 111b, and a thickness of the partition wall portion 111a is taken perpendicular to the length thereof. A length of the bezel portion 111b extends in the thickness direction of the partition wall portion 111a.

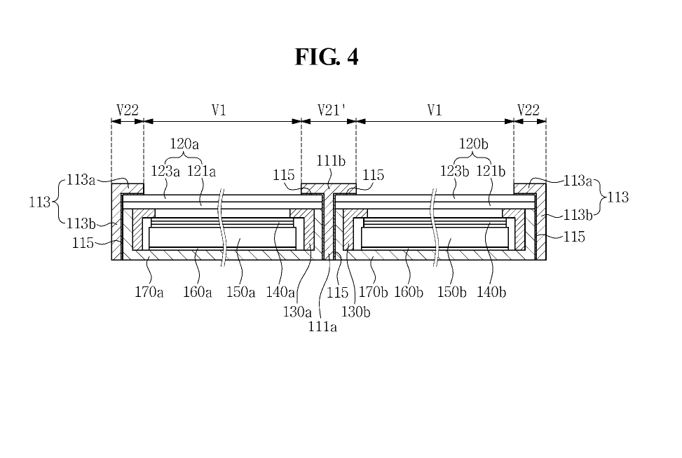

Since adjacent display panel among the display panels 120a, 120b, 120c and 120d share a single first upper frame 111, the multi-display device 100 may have a first non-display area V21′ between the adjacent display panel among the display panels 120a, 120b, 120c, and 120d. Portions of the first non-display area V21′ of the multi-display device 100 is defined by first display areas V21 of the adjacent display panels and the upper frame 111. The second non-display area (V22 in FIG. 4) and the display area (V1 in FIG. 4) of the multi-display device 100 may be respectively defined by the second non-display areas V22 and the display areas V1 of the adjacent display panels (refer to FIG. 2), but the invention is not limited thereto.

In a conventional multi-display device, separate frames respectively corresponding to adjacent display panels may be disposed at inner areas of the multi-display device where the display panels are adjacent to each other. Where separate frames are disposed between adjacent display panels, separate partition wall portions are disposed between adjacent display panels to undesirably increase a width of the inner area non-display area of the multi-display device. In contrast, in one or more exemplary embodiment according to the invention, adjacent display panels among a plurality of display panels share a single frame, where the single frame has only one partition wall portion. Where a single frame with a single partition wall portion is disposed between adjacent display panels, a width of the inner area non-display area of the multi-display device may be reduced by a thickness of a partition wall portion as compared to the conventional multi-display device.

The second upper frame 113 may be disposed to cover an outer edge of the multi-display device 100 and a lateral side surface thereof. The second upper frame 113 may include an outer edge bezel portion 113a disposed on the second non-display area V22, and a lateral wall portion 113b bent downwards from the outer edge bezel portion 113a and extending therefrom.

A fixing member such as an adhesive 115 may further be disposed between the first upper frame 111 and respective display panels 120a, 120b, 120c and 120d and between the second upper frame 113 and respective display panels 120a, 120b, 120c, and 120d. The adhesive 115 may be a double-sided tape, and any adhesive used in common may be applicable without limitation.

FIG. 4 is a cross-sectional view taken along line I-I of FIG. 1. Since configurations of adjacent display panels among the plurality of display panels of the multi-display apparatus 100 are the same, adjacent display panels 120a and 120b are described below for purposes of illustration.

In reference to FIG. 4, the multi-display device 100 may include the first upper frame 111, the second upper frame 113, the display panels 120a and 120b disposed adjacent to each other, middle frames 130a and 130b, optical sheets 140a and 140b, light guide plates 150a and 150b, reflection sheets 160a and 160b, and lower frames 170a and 170b.

Hereinafter, the middle frames 130a and 130b, the optical sheets 140a and 140b, the light guide plates 150a and 150b, the reflection sheets 160a and 160b, and the lower frames 170a and 170b are to be collectively referred to as a backlight unit.

The display panels 120a and 120b may be provided in a quadrangular plate form in a top plan view and display an image using light. The display panels 120a and 120b may be various types of display panels, such as an LCD panel or an electrophoretic display (“EPD”) panel. Herein, for convenience of explanation, the exemplary embodiment of the multi-display device 100 is described where the display panels 120a and 120b are LCD panels.

The display panels 120a and 120b may each include first display substrates 121a and 121b, second display substrates 123a and 123b opposing the first display substrates 121a and 121b, and a liquid crystal layer (not illustrated) disposed between the first display substrates 121a and 121b facing the second display substrates 123a and 123b, respectively.

The first display substrates 121a and 121b may include a plurality of pixel electrodes arranged in a matrix form on a first base substrate therein, a thin film transistor applying a driving voltage to the respective pixel electrodes on the first base substrate, and various signal wirings for driving the pixel electrode and the thin film transistor on the first base substrate.

The second display substrates 123a and 123b may be disposed to oppose the first display substrates 121a and 121b, respectively, and may include a common electrode including or formed of a transparent conductive material and a color filter on a second base substrate. The color filter may include a red color filter, a green color filter and a blue color filter, but the invention is not limited thereto.

The liquid crystal layer (not illustrated) may be interposed between the first display substrates 121a and 121b facing the second display substrates 123a and 123b, respectively. Orientations of liquid crystal of the liquid crystal layer may be rearranged by an electric field generated between the pixel electrode and the common electrode. Accordingly, the rearranged liquid crystal layer may adjust a level of transmittance of light emitted from the backlight unit, and the adjusted light may pass through the color filter to display an image outwards (e.g., upwards in FIG. 4 toward a viewing side of the multi-display device 100).

In addition, a lower polarizing plate (not illustrated) and an upper polarizing plate (not illustrated) may further be disposed on lower surfaces of the first display substrates 121a and 121b and on upper surfaces of the second display substrates 123a and 123b, respectively. The upper polarizing plate (not illustrated) and the lower polarizing plate (not illustrated) may each have a planar area in the top plan view corresponding to a planar area of the display panels 120a and 120b in the top plan view. For purposes of description, a polarizing plate may be considered a portion of a display substrate.

The upper polarizing plate (not illustrated) may pass therethrough a predetermined component of polarized light from among externally supplied light incident thereto, and may absorb or block the remainder of the externally supplied light. The lower polarizing plate (not illustrated) may pass therethrough a predetermined component of polarized light from among the light emitted from the backlight unit incident thereto, and may absorb or block the remainder of the light emitted from the backlight unit.

The middle frames 130a and 130b may have a quadrangular loop shape in the top plan view, and may accommodate therein and support the display panels 120a and 120b, the optical sheets 140a and 140b, and the light guide plates 150a and 150b. The middle frames 130a and 130b may be provided as a single unit, such that a middle frame defines the portions thereof. Alternatively, a plurality of units may be assembled to form the middle frames 130a and 130b, where necessary.

The middle frames 130a and 130b may include at least one of an epoxy resin material or composition, a silicon resin material or composition, a modified epoxy resin material or composition such as a silicon-modified epoxy resin, a modified silicon resin material or composition such as an epoxy-modified silicon resin, a polyimid resin material or composition, a modified polyimide resin material or composition, polyphthalamide (“PPA”), a polycarbonate (“PC”) resin, polyphenylene sulfide (“PPS”), a liquid crystal polymer (“LCP”), an acrylonitrile butadiene styrene (“ABS”) resin, a phenol resin, an acrylic resin, and a polybutylene terephthalate (“PBT”) resin.

The optical sheets 140a and 140b may be disposed on the light guide plates 150a and 150b, respectively, and may serve to diffuse or collimate light transmitted from the light guide plates 150a and 150b. Each of the optical sheets 140a and 140b may collectively include a diffusion sheet, a prism sheet and a protection sheet, but the invention is not limited thereto.

The diffusion sheet may disperse light that is incident to the light guide plates 150a and 150b so as to reduce or effectively prevent concentration of the light at a predetermined area.

The prism sheet may include prisms having a triangular cross-section in a predetermined arrangement on a surface thereof. The prism sheet may be disposed on the diffusion sheet and may collimate light diffused from the diffusion sheet in a direction perpendicular to the display panels 120a and 120b

The protection sheet may be disposed on the prism sheet and may serve to protect a surface of the prism sheet and diffuse light to achieve uniform light distribution at the display panels 120a and 120b.

The backlight unit may further include a light source which generates and provides light used by the display panels 120a and 120b to display an image. The light guide plates 150a and 150b may uniformly supply light transmitted from the light source to the display panels 120a and 120b, respectively. The light guide plates 150a and 150b may include a quadrangular plate shape having a substantially uniform cross-sectional thickness, but the invention is not limited thereto. When a light emitting diode (“LED”) chip is used as the light source, the light guide plates 150a and 150b may have various forms including predetermined grooves defined therein, protrusions defined therein, a wedge shape, or the like depending on the position of the light source.

Herein, the light guide plates 150a and 150b are described as a plate having a relatively large cross-sectional thickness for ease of description, but the invention is not limited thereto. The light guide plates 150a and 150b in a sheet or film form for which the cross-sectional thickness is smaller than that of the plate and is relatively small as compared to the planar size thereof, to achieve an overall reduced thickness and slimness of the display panels 120a and 120b and consequently, the multi-display device including the display panels 120a and 120b. That is, the light guide plates 150a and 150b are to be understood as having a concept that includes not only a plate but also a film which guides light provided from the light source.

The light guide plates 150a and 150b may include or be formed of a light-transmissive material such as, for example, an acrylic resin, such as polymethylmethacrylate (“PMMA”) or polycarbonate (“PC”) so as to guide light efficiently.

The reflection sheets 160a and 160b may be disposed between the light guide plates 150a and 150b and the lower frames 170a and 170b, respectively. The reflection sheets 160a and 160b may reflect light emitted downwards from the light guide plates 150a and 150b to be red-directed toward the display panels 120a and 120b, thereby improving light efficiency.

The reflection sheets 160a and 160b may include, for example, polyethylene terephthalate (“PET”), and may reflect light. A surface of the reflection sheets 160a and 160b may be coated with a diffusion layer including, for example, titanium dioxide. The reflection sheets 160a and 160b may include a material containing metal, such as silver (Ag).

The lower frames 170a and 170b may include at least one of stainless steel, aluminum, aluminum alloys, magnesium, magnesium alloys, copper, copper alloys, and an electro-galvanized steel sheet, but the invention is not limited thereto. The lower frames 170a and 170b may maintain an overall framework of the display panels 120a and 120b and/or of the multi-display device 100 including the display panels 120a and 120b, and may protect various components accommodated therein.

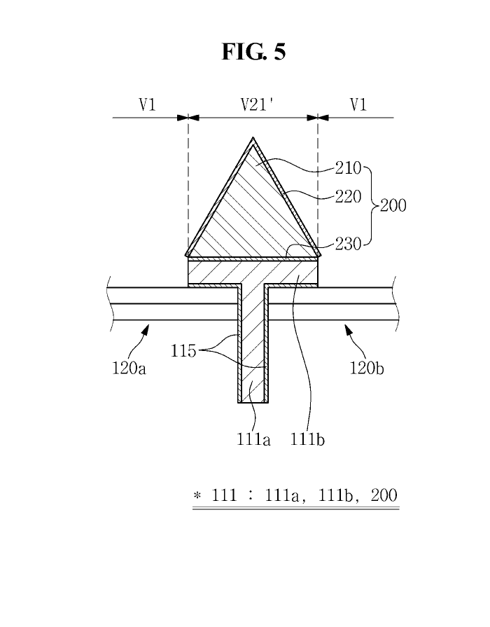

FIGS. 5, 6 and 7 are cross-sectional views illustrating other exemplary embodiments of a multi-display device according to the invention. Since like reference numerals refer to like elements throughout the specification, repeated descriptions from the previous exemplary embodiments will be omitted.

In reference to FIG. 5, another exemplary embodiment of a multi-display device according to the invention may include display panels 120a and 120b disposed adjacent to each other, and a first upper frame 111 disposed between the adjacent display panels 120a and 120b.

The first upper frame 111 may include a partition wall portion 111a disposed between the adjacent display panels 120a and 120b, and a bezel portion 111b bent from the partition wall portion 111a to extend therefrom. The bezel portion 111b is disposed in a first non-display area V21 of the respective display panels 120a and 120b. The first upper frame 111 may further include an optical structure 200 disposed on the bezel portion 111b at a viewing side of the multi-display device. The partition wall portion 111a may be disposed between the adjacent display panels 120a and 120b.

The optical structure 200 may include a transparent body 210 having a bar shape defined by a length thereof extending along a length of the bezel portion 111a in the top plan view, a reflection member 220 disposed on at least one surface of the transparent body 210 such as a viewing-side surface thereof, and an adhesive 230 which fixes the transparent body 210 to the bezel portion 111a.

The transparent body 210 may have a triangular cross-section, but the invention is not limited thereto. In exemplary embodiments, the transparent body 210 may have a quadrangular, circular or other shape in cross-section.

The transparent body 210 may include at least one of polycarbonate (“PC”), polymethyl methacrylate (“PMMA”), an acrylonitrile-butadiene-styrene (“ABS”) copolymer and an acrylic resin.

The reflection member 220 may include a reflective material including at least one of gold (Au), silver (Ag), copper (Cu), aluminum (Al), chromium (Cr), titanium (Ti) and a metal alloy thereof. In an exemplary embodiment of manufacturing a multi-display device, the reflection member 220 may be formed through various methods, such as a deposition process, a coating process, a painting process or a film adhesion process.

The adhesive 230 may include any of a number of transparent adhesives without limitation. In an exemplary embodiment, for example, the adhesive 230 may be an optical clear adhesive (“OCA”) or an optical clear resin (“OCR”).

The optical structure 200 may reflect light emitted from a display area V1 so as to reduce or effectively prevent visibility of the non-display area V21′ adjacent to the display area V1.

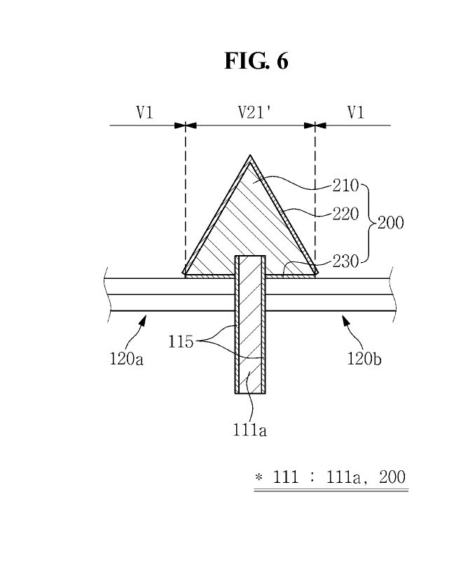

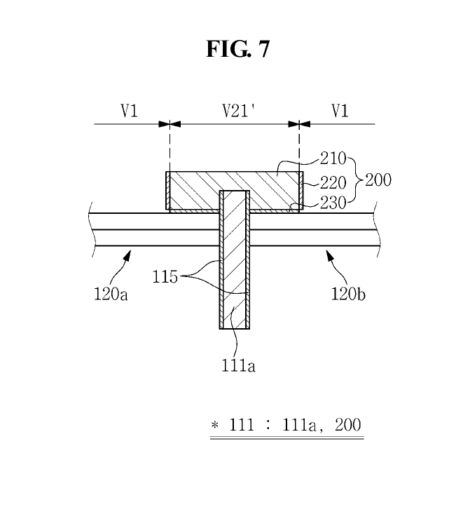

In reference to FIGS. 6 and 7, still other exemplary embodiments of a multi-display device according to the invention may include display panels 120a and 120b disposed adjacent to each other, and a first upper frame 111 disposed between the adjacent display panels 120a and 120b.

The first upper frame 111 may include a partition wall portion 111a disposed between the adjacent display panels 120a and 120b, and an optical structure 200 coupled to the partition wall portion 111a at a viewing side of the multi-display device. The partition wall portion 111a may be disposed between the adjacent display panels 120a and 120b.

An adhesive 115 disposed between the partition wall portion 111a and the respective display panels 120a and 120b may extend to be further disposed between the partition wall portion 111a and the optical structure 200.

Since the first frame 111 illustrated in FIG. 6 and FIG. 7 omits the bezel portion (refer to 111b of FIG. 5), the partition wall portion 111a disposed between the adjacent display panels 120a and 120b may extend to be disposed in the optical structure 200. The optical structure 200 may be disposed within the first non-display area V21′ of the multi-display device and may extend to be disposed in first non-display areas V21 of the display panels 120a and 120b disposed adjacent to each other.

The optical structure 200 may include a transparent body 210 having a bar shape defined by a length thereof extending along a length of the first non-display areas V21 in the top plan view of the display panels 120a and 120b disposed adjacent to each other, a reflection member 220 disposed on at least one surface of the transparent body 210 such as a viewing-side surface thereof, and an adhesive 230 which fixes the transparent body 210 to the first non-display areas V21 of the adjacent display panels 120a and 120b.

The transparent body 210 may have a triangular cross-section (refer to FIG. 6) or a quadrangular cross-section (refer to FIG. 7), but the invention is not limited thereto. In exemplary embodiments, the transparent body 210 may have a circular or other shape cross-section.

The transparent body 210 may include at least one of polycarbonate (PC), polymethyl methacrylate (“PMMA”), an acrylonitrile-butadiene-styrene (“ABS”) copolymer, and an acrylic resin.

The reflection member 220 may include a reflective material including at least one of gold (Au), silver (Ag), copper (Cu), aluminum (Al), chromium (Cr), titanium (Ti) and a metal alloy thereof. In an exemplary embodiment of manufacturing a multi-display device, the reflection member 220 may be formed through various methods, such as a deposition process, a coating process, a painting process or a film adhesion process.

The adhesive 230 may include any of a number of transparent adhesives without limitation. In an exemplary embodiment, for example, the adhesive 230 may be an optical clear adhesive (“OCA”) or an optical clear resin (“OCR”).

The optical structure 200 may reflect light emitted from a display area V1, and thus visibility of the non-display area V21′ adjacent to the display area V1 may be reduced or effectively prevented.

As set forth above, one or more exemplary embodiment of the multi-display device according to the invention has a structure in which adjacent display panels among a plurality of display panels share a single frame, and thus a width of an overall non-display area of a multi-display device including the adjacent display panels may be reduced by a thickness of a portion of the frame. Further, the multi-display device including the adjacent display panels may include an optical structure at the shared single frame between the adjacent display panels, and thus visibility of the non-display area of the multi-display device may be efficiently reduced.

From the foregoing, it will be appreciated that various exemplary embodiments in accordance with the invention have been described herein for purposes of illustration, and that various modifications may be made without departing from the scope and spirit of the present teachings. Accordingly, the various exemplary embodiments disclosed herein are not intended to be limiting of the true scope and spirit of the invention.

What is claimed is:

1. A multi-display device comprising:
a plurality of display panels adjacent to each other; and
a first upper frame between the display panels adjacent to each other,
wherein the first upper frame comprises:
a partition wall portion between the display panels adjacent to each other; and
a bezel portion extended from the partition wall portion to overlap front surface edges the display panels adjacent to each other.

2. The multi-display device of claim 1, wherein
each of the plurality of display panels includes a display area in which an image is displayed and a non-display area around the display area and in which the image is not displayed, and
the first upper frame bezel portion is disposed in the non-display area of each the display panels adjacent to each other.

3. The multi-display device of claim 2, further comprising a second upper frame comprising:
an outer edge bezel portion in the non-display area at an outer edge of the multi-display device; and
a lateral wall portion extended downwards from the outer edge bezel portion along an outer side surface of the multi-display device.

4. The multi-display device of claim 3, wherein the first upper frame and the second upper frame each comprise at least one of stainless steel, aluminum, aluminum alloys, magnesium, magnesium alloys, copper, copper alloys and an electro-galvanized steel sheet.

5. The multi-display device of claim 3, further comprising an adhesive between the first upper frame and the display panels adjacent to each other and between the second upper frame and the display panels adjacent to each other.

6. The multi-display device of claim 1, wherein the first upper frame further comprises an optical structure on the bezel portion.

7. The multi-display device of claim 6, wherein the optical structure has one of a triangular, quadrangular and circular cross-section.

8. The multi-display device of claim 6, wherein the optical structure comprises at least one of polycarbonate, polymethyl methacrylate, an acrylonitrile-butadiene-styrene copolymer and an acrylic resin.

9. The multi-display device of claim 6, wherein the first upper frame further comprises a reflection member, the reflection member on an outer surface of the optical structure.

10. The multi-display device of claim 9, wherein the reflection member comprises at least one of gold, silver, copper, aluminum, chromium, titanium and a metal alloy thereof.

11. The multi-display device of claim 6, further comprising an adhesive between the bezel portion and the optical structure, the adhesive fixing the bezel portion to the optical structure.

12. A multi-display device comprising:
a plurality of display panels adjacent to each other; and
a first upper frame between the display panels adjacent to each other,
wherein the first upper frame comprises:
an optical structure which extends to overlap front surface edges of the display panels adjacent to each other; and
a partition wall portion between the display panels adjacent to each other, the partition wall portion extended into the optical structure which extends to overlap the front surface edges of the display panels adjacent to each other.

13. The multi-display device of claim 12, wherein
each of the plurality of display panels include a display area in which an image is displayed, and a non-display area around the display area and in which the image is not displayed, and
the optical structure is disposed in the non-display area of each of the display panels adjacent to each other.

14. The multi-display device of claim 13, further comprising a second upper frame comprising:
an outer edge bezel portion in the non-display area at an outer edge of the multi-display device; and
a lateral wall portion extended downwards from the outer edge bezel portion along an outer side surface of the multi-display device.

15. The multi-display device of claim 14, wherein the first frame partition wall portion and the second upper frame each comprise at least one of stainless steel, aluminum, aluminum alloys, magnesium, magnesium alloys, copper, copper alloys and an electro-galvanized steel sheet.

16. The multi-display device of claim 12, wherein the optical structure comprises at least one of polycarbonate, polymethyl methacrylate, an acrylonitrile-butadiene-styrene copolymer and an acrylic resin.

17. The multi-display device of claim 12, further comprising an adhesive between the optical structure and the display panels adjacent to each other, the adhesive fixing the optical structure to the adjacent display panels of which the front surface edges thereof area overlapped by the optical structure.

18. The multi-display device of claim 12, wherein the optical structure has one of a triangular, quadrangular and circular cross-section.

19. The multi-display device of claim 12, wherein the first upper frame comprises a reflection member, the reflection member on an outer surface of the optical structure.

20. The multi-display device of claim 19, wherein the reflection member comprises at least one of gold, silver, copper, aluminum, chromium, titanium and a metal alloy thereof.
